(19) United States
(12) Patent Application Publication
(10) Pub. No.: US 2013/0087191 A1
(43) Pub. Date: Apr. 11, 2013

(54) POINT-CONTACT SOLAR CELL STRUCTURE

(71) Applicants: Seow-Wei TAN, Taipei (TW); Yen-Yu Chen, Taipei (TW); Wei-Shuo Ho, Taipei (TW); Yu-Hung Huang, Taipei (TW); Chee-Wee Liu, Taipei (TW)

(72) Inventors: Seow-Wei TAN, Taipei (TW); Yen-Yu Chen, Taipei (TW); Wei-Shuo Ho, Taipei (TW); Yu-Hung Huang, Taipei (TW); Chee-Wee Liu, Taipei (TW)

(21) Appl. No.: 13/341,526

(22) Filed: Dec. 30, 2011

(30) Foreign Application Priority Data
Oct. 7, 2011 (TW) 100136523

(51) Int. Cl. H01L 31/0224; H01L 31/0216

(52) U.S. Cl. 136/256

(57) ABSTRACT

A point-contact solar cell structure includes a semiconductor substrate, a front electrode, a first passivation layer, a second passivation layer, and a rear electrode. The semiconductor substrate includes an upper surface, a lower surface, and an emitter layer, a base layer, and a plurality of locally doped regions located between the upper surface and the lower surface. The plurality of locally doped regions is located on the lower surface at intervals. The second passivation layer is located on the lower surface, and has a plurality of openings disposed respectively corresponding to the locally doped regions. The rear electrode is located on one side of the second passivation layer opposite to the semiconductor substrate, and passes through the second passivation layer via the openings to contact the locally doped regions. The width of at least one opening corresponding to the front electrode is greater than that of the remaining openings.

### CROSS-REFERENCES TO RELATED APPLICATIONS

This non-provisional application claims priority under 35 U.S.C. §119(a) on Patent Application No. 100136523 filed in Taiwan, R.O.C. on 2011 Oct. 7, the entire contents of which are hereby incorporated by reference.

### BACKGROUND

1. Technical Field

The disclosure relates to a solar cell structure, and more particularly to a point-contact solar cell structure.

2. Related Art

FIG. 1 is a three-dimensional view of a solar cell structure 100a. Please refer to FIG. 1, the solar cell may include a silicon semiconductor 110a, a front electrode 130a, a rear electrode 150a, and an anti-reflection coating (ARC) 170a capable of increasing the light incidence amount. The silicon semiconductor 110a includes a P-type silicon layer 112a, an N-type silicon layer 114a, and a P-N junction 116a formed between the P-type silicon layer 112a and the N-type silicon layer 114a. When the photon-enters a depletion region located on the P-N junction 116a, electron (e⁻) hole (h⁺) pairs are generated, but due to the effect of an internal electric field of the P-N junction 116a, the electrons (e⁻) are gathered towards the front electrode 130a, and the holes (h⁺) are gathered towards the rear electrode 150a, to achieve the purpose of power supply. Also, beyond the depletion region, the electron hole pairs also can be generated and collected by the electrode.

However, an interface between the silicon and the conductive material may easily cause surface recombination, so that the conversion efficiency of the solar cell is lowered. A solar cell structure 100a′ shown in FIG. 2 is therefore provided, which is added with a heavily doped P-type silicon layer 118a as compared with FIG. 1. In this manner, an energy barrier is formed between the P-type silicon layer 112a and the heavily doped P-type silicon layer 118a, to prevent the electrons on the P-type silicon layer 112a from moving towards the P-type region, thereby lowering the surface recombination rate.

Alternatively, to reduce the surface recombination rate, the rear electrode 150a may adopt a point-contact structure (see U.S. Pat. No. 6,524,880), and the contact area between the silicon and the conductive material is reduced. The surface recombination is therefore reduced, improving the fill factor (FF) of the solar cell, so as to enhance the conversion efficiency of the solar cell.

In view of these facts, improving the FF of the solar cell to enhance the conversion efficiency is a problem requiring urgent solution by the inventor and those involved in the field.

### SUMMARY

Accordingly, in an embodiment of the disclosure, a point-contact solar cell structure is disclosed to solve the problem in the prior art.

In an embodiment, a point-contact solar cell structure includes a semiconductor substrate, a front electrode, a first passivation layer, a second passivation layer, and a rear electrode.

The semiconductor substrate includes an upper surface, a lower surface, a plurality of locally doped regions, an emitter layer, and a base layer. The lower surface is opposite to the upper surface. The plurality of locally doped regions is located on the lower surface at intervals to form a back-side surface field (BSF). The emitter layer is located on the upper surface. The base layer is located between the emitter layer and the BSF.

The front electrode is located on the upper surface of the semiconductor substrate. The first passivation layer is also located on the upper surface of the semiconductor substrate, and is connected to the front electrode. The second passivation layer is located on the lower surface of the semiconductor substrate, and has a plurality of openings disposed respectively corresponding to the locally doped regions. The rear electrode is located on one side of the second passivation layer opposite to the semiconductor substrate, and passes through the second passivation layer via the openings to contact the locally doped regions. The width of at least one opening corresponding to the front electrode is greater than that of the remaining openings.

Through the disclosed point-contact solar cell structure, the FF of the solar cell is improved, and the conversion efficiency is enhanced.

### BRIEF DESCRIPTION OF THE DRAWINGS

The disclosure will become more fully understood from the detailed description given herein below for illustration only and thus not limitative of the disclosure, wherein:

FIG. 1 is a three-dimensional view of a-a conventional solar cell structure;

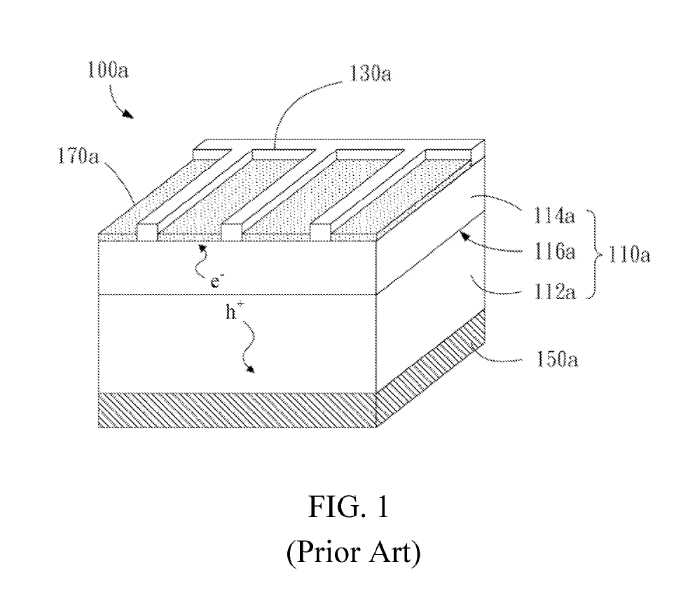

FIG. 2 is a cross-sectional view of another conventional solar cell structure;

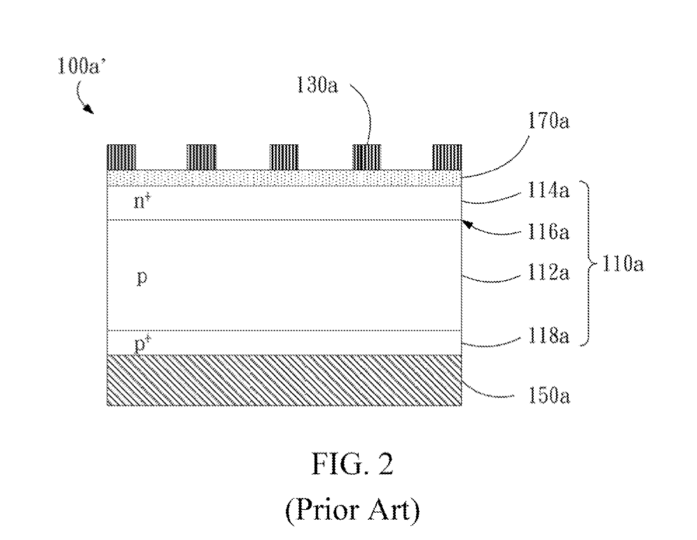

FIG. 3 is a top view of a point-contact solar cell structure according to an embodiment;

FIG. 4 is a cross-sectional view of FIG. 3 along Section line B-B;

FIG. 5 is a bottom view of a semiconductor substrate at a position A in FIG. 3; and

FIG. 6 is a top view of a second passivation layer and a rear electrode at the position A in FIG. 3.

### DETAILED DESCRIPTION

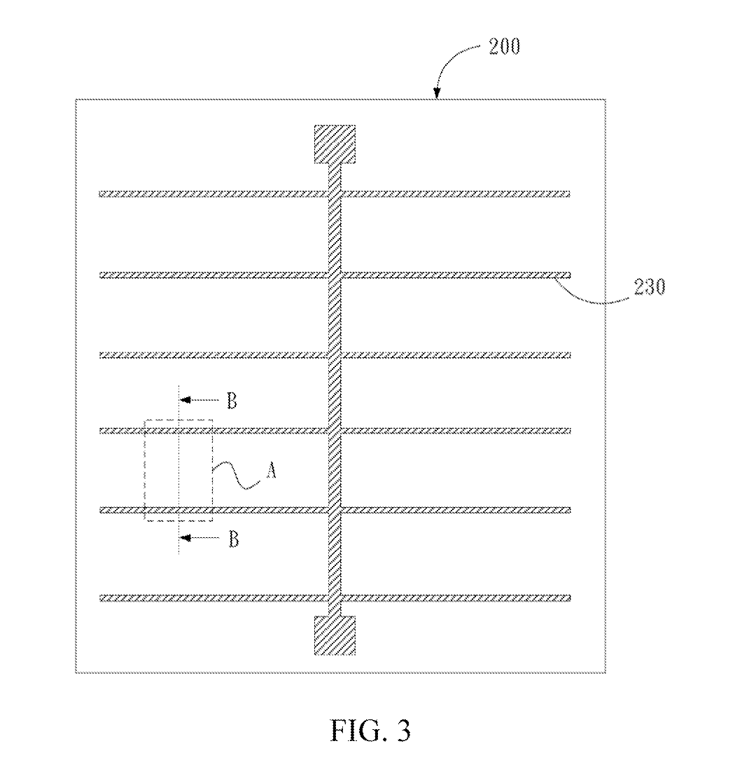

FIG. 3 is a top view of a point-contact solar cell structure 200 according to an embodiment. Please refer to FIG. 3, in which the point-contact solar cell structure 200 of this embodiment may have an interdigitated front electrode 230.

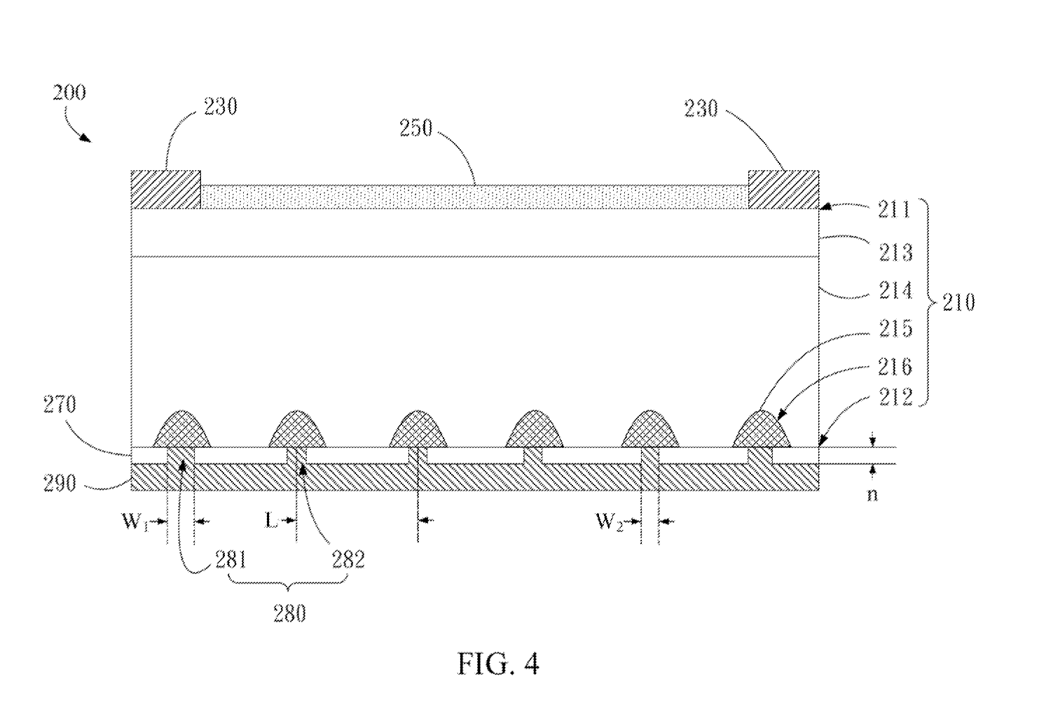

FIG. 4 is a cross-sectional view of FIG. 3 along Section line B-B. Please refer to FIG. 4, in which the point-contact solar cell structure 200 includes a semiconductor substrate 210, a front electrode 230, a first passivation layer 250, a second passivation layer 270, and a rear electrode 290.

The semiconductor substrate 210 includes an upper surface 211 and an opposite lower surface 212. The front electrode 230 is located on the upper surface 211 of the semiconductor substrate 210. The first passivation layer 250 is also located on the upper surface 211 of the semiconductor substrate 210, and is connected to the front electrode 230.

The second passivation layer 270 is located on the lower surface 212 of the semiconductor substrate 210. The rear electrode 290 is located on one side of the second passivation layer 270 opposite to the semiconductor substrate 210.

The upper surface 211 is a light incident surface, for receiving the light energy to facilitate the photovoltaic effect of the point-contact solar cell structure 200. The first passivation layer 250 is also referred to as an ARC, for reducing the probability that the incident light returns after being reflected once. The first passivation layer 250 may be formed by a passivation material such as silicon dioxide, silicon nitride, or aluminum oxide. Surface treatment may be performed on the first passivation layer 250; for example, pyramid structures of different sizes may be formed on a surface of the first passivation layer 250, to reduce the probability that the incident light returns after being reflected once.

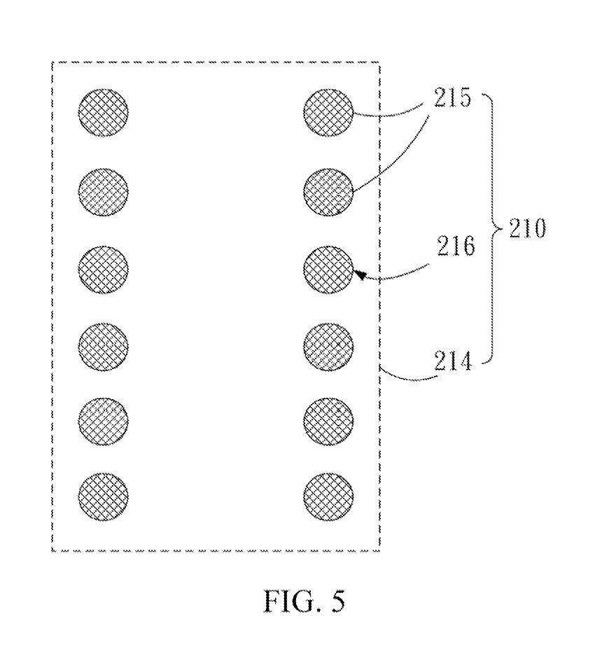

FIG. 5 is a bottom view of the semiconductor substrate 210 at a position A in FIG. 3. Please refer to FIG. 4 and FIG. 5 together, in which the semiconductor substrate 210 further includes an emitter layer 213, a base layer 214, and a plurality of locally doped regions 215 disposed between the upper surface 211 and the lower surface 212. The emitter layer 213 is located on the upper surface 211. The locally doped regions 215 are located on the lower surface 212 at intervals to form a BSF 216. The base layer 214 is located between the emitter layer 213 and the BSF 216.

The semiconductor substrate 210 may be formed by single crystalline material, polycrystalline material, or amorphous material. In an embodiment, the semiconductor substrate 210 may be substantially formed by a material such as single crystalline silicon, polycrystalline silicon, or amorphous silicon.

The semiconductor substrate 210 may be formed by a wafer of an N-type or a P-type base material. Taking the P-type wafer for example, an N-type (N⁺) emitter layer 213 may be formed on a heavily doped donor of the semiconductor substrate 210. Similarly, P-type (P⁺) locally doped regions 215 may be formed on a heavily doped acceptor of the semiconductor substrate 210. The donor may be a Group V element, such as phosphorus, arsenic, or antimony, and the acceptor may be a Group III element, such as aluminium, gallium, or indium. In this way, the emitter layer 213, the base layer 214, and the BSF 216 may form a junction of an N⁺PP⁺ structure.

Similarly, when the N-type wafer is used to manufacture the semiconductor substrate 210, a junction of a P⁺NN⁺ structure is formed. The emitter layer 213 is of an N-type (N⁺), and the locally doped region 215 is of a P-type (P⁺).

The heavy doping may be implemented through laser anneal, diffusion, or ion implantation.

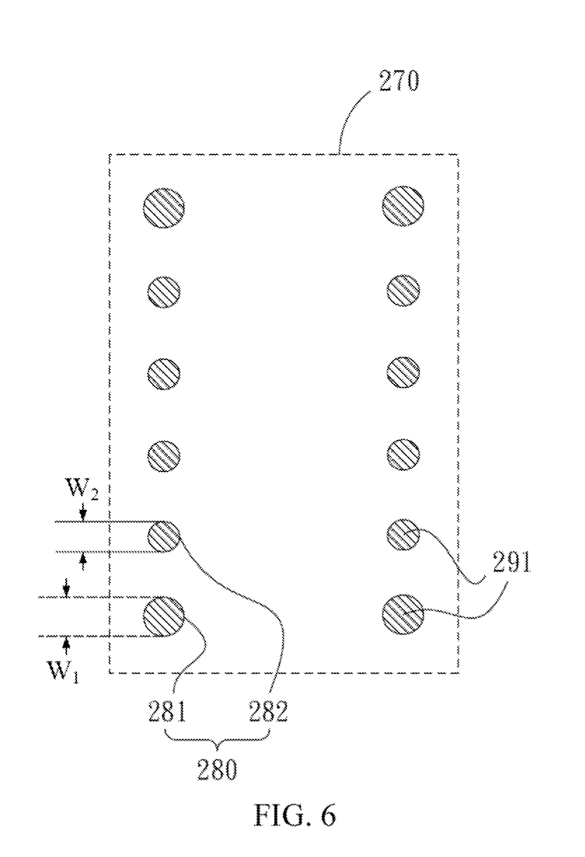

FIG. 6 is a top view of the second passivation layer 270 and the rear electrode 290 at the position A in FIG. 3. Please refer to FIG. 4 to FIG. 6 together, in which the second passivation layer 270 has a plurality of openings 280, disposed respectively corresponding to the locally doped regions 215. The rear electrode 290 may therefore pass through the second passivation layer 270 via the openings 280 to contact the locally doped regions 215. Specifically, the rear electrode 290 includes a plurality of point contacts 291. The point contacts 291 protrude from a surface of the rear electrode 290, and respectively pass through the openings 280 to contact the corresponding locally doped regions 215.

The second passivation layer 270 is formed by a passivation material, for example, silicon dioxide, silicon nitride, TiO₂, or aluminum oxide. The second passivation layer 270 may be manufactured by laser etching, lithography, or etching. The above method may be selected according to the required size of the openings 280. After the manufacturing of the openings 280, the rear electrode 290 may be formed by a laser, physical or chemical processing method or a combination thereof, such as laser sintering or screen printing.

The current density below the front electrode 230 is greater than that of other places. Consequently, when the width of at least one opening 280 corresponding to the front electrode 230 is greater than that of the remaining openings, the FF of the point-contact solar cell structure 200 is improved, and the conversion efficiency is enhanced.

Table 1 shows test results of the point-contact solar cell structure 200 in FIG. 3 having different opening widths. Please refer to FIGS. 4 and 6, in which for ease of illustration the openings 280 located below the first passivation layer are referred to as first openings 281, and the other openings are referred to as second openings 282.

TABLE 1
Test results of the point-contact solar cell
structure having different opening widths

| First | Second | | | | | |
|---|---|---|---|---|---|---|
| opening | opening | | | | | |
| width | width | Metallization | J_{sc} | V_{oc} | FF | Efficiency |
| (μm) | (μm) | (%) | (mA/cm²) | (V) | (%) | (%) |
| 10 | 10 | 3.8 | 32.26 | 0.6259 | 80.47 | 16.25 |
| 10 + 5 | 10 | 4.5 | 32.26 | 0.6259 | 80.48 | 16.25 |
| 10 + 20 | 10 | 6.4 | 32.26 | 0.6258 | 80.52 | 16.26 |

Table 1 shows the corresponding short circuit current density J_{sc}, the open circuit voltage V_{oc}, the FF, and the photoelectric conversion efficiency η when the width of the second opening 282 is 10 μm, and the width of the first opening 281 is respectively increased by 0 μm, 5 μm, and 20 μm as compared with the second opening 282. It can be seen that when the width of the first opening 281 is increased by 5 μm or 20 μm as compared with the second opening 282, a more desirable FF can be provided than the circumstance that the width of the first opening 281 is equal to that of the second opening 282.

Preferably, a distance between the centers of two adjacent openings 280 (that is, the opening length L) is in a range of 90 μm to 300 μm. The width (W₂) of the second opening 282 is in a range of 10 μm to 30 μm. The width (W₁) of the first opening 281 is greater than the width (W₂) of the second opening 282 by 5 μm to 20 μm. That is, the width of the first opening 281 is in a range of 15 μm to 50 μm. In addition, the thickness (n) of the second passivation layer 270 is preferably 100 nm.

To maintain the clarity of the drawings, in FIG. 4 to FIG. 6 the locally doped regions 215, the openings 280, and the point contacts 291 are only shown with simplified numbers. Furthermore, on the basis of this description of the width and distance of the openings 280, it is apparent to those skilled in the art the actual numbers of the locally doped regions 215, the openings 280, and the point contacts 291 in the implementation of the embodiment.

Given these facts, in the embodiment the FF can be improved by adjusting the size of the point contacts 291 below the front electrode 230, so as to achieve higher conversion efficiency.

While the disclosure has been described by the way of example and in terms of the preferred embodiments, it is to be understood that the disclosure need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A point-contact solar cell structure, comprising:
a semiconductor substrate, comprising:
an upper surface;
a lower surface, opposite to the upper surface;
a plurality of locally doped regions, located on the lower surface at intervals to form a back-side surface field (BSF);
an emitter layer, located on the upper surface; and
a base layer, located between the emitter layer and the BSF;
a front electrode, located on the upper surface of the semiconductor substrate;
a first passivation layer, located on the upper surface of the semiconductor substrate, and connected to the front electrode;
a second passivation layer, located on the lower surface of the semiconductor substrate, and having a plurality of openings disposed respectively corresponding to the locally doped regions; and
a rear electrode, located on one side of the second passivation layer opposite to the semiconductor substrate, and passing through the second passivation layer via the openings to contact the locally doped regions,
wherein the width of at least one opening corresponding to the front electrode is greater than that of the remaining openings.

2. The solar cell structure according to claim 1, wherein the emitter layer, the base layer, and the BSF form a P⁺NN⁺ or an N⁺PP⁺ junction.

3. The solar cell structure according to claim 1, wherein the material of the semiconductor substrate is selected from the group consisting of single crystalline silicon, polycrystalline silicon, and amorphous silicon.

4. The solar cell structure according to claim 1, wherein the material of the second passivation layer is selected from the group consisting of silicon dioxide, silicon nitride, and aluminum oxide.

5. The solar cell structure according to claim 1, wherein a distance between the centers of two adjacent openings is in a range of 90 μm to 300 μm.

6. The solar cell structure according to claim 1, wherein the width of the openings located below the first passivation layer is in a range of 10 μm to 30 μm.

7. The solar cell structure according to claim 1, wherein the width of the openings located below the front electrode is in a range of 15 μm to 50 μm.

8. The solar cell structure according to claim 1, wherein the width of the openings located below the front electrode is greater than that of the openings located below the first passivation layer by 5 μm to 20 μm.

9. The solar cell structure according to claim 1, wherein the width of the second passivation layer is 100 nm.

10. The solar cell structure according to claim 1, wherein the rear electrode comprises a plurality of point contacts, protruding from a surface of the rear electrode and passing through the openings to contact the locally doped regions.
